(19) United States
(12) Patent Application Publication
(10) Pub. No.: US 2010/0195302 A1
(43) Pub. Date: Aug. 5, 2010

(54) Flexible guiding module

(76) Inventor: William J. Rigby, Somis, CA (US)

Correspondence Address: SANDRA LEE LIPKIN A LAW CORPORATION, P.O.Box 3518, VENTURA, CA, 93006, US

(21) Appl. No.: 12/322,560

(22) Filed: Feb. 3, 2009

(51) Int. Cl. H05K 1/14

(52) U.S. Cl. 361/784

(57) ABSTRACT

A flexible guiding module for electronic connector backplane enclosures having one or more molded plastic prongs or protrusions from a base body that is attached to the back plane by a threaded screw and secured to the base body by a threaded insert or directly by a threaded hole in the base body. The plastic prongs or protrusions are molded of high impact plastic having a spring back memory giving flexible guidance at the top or tip of the prongs or protrusions and gradually having additionally more accurate alignment at the base body when mated with the plug in card. This flexible polyether imide plastic guiding module is also resilient to damage caused by bent metal pins that can damage the plug in card or daughter card.

### BACKGROUND OF THE INVENTION

1. Field of the Invention

The present invention relates generally to the field of back plane assemblies, and more particularly to an assembly for positioning a daughter board relative to a back plane.

2. Description of the Prior Art

Multiple printed circuit boards are commonly connected together through another printed circuit board called a “back plane.” A back plane is a circuit board that connects several connectors in parallel to each other, so that each pin of each connector is linked to the same relative pin of all the other connectors, forming a computer bus. It is used as a backbone to connect several printed circuit boards together to make up a complete computer system. When printed circuit boards are connected together in this fashion, they are generally known as “daughter boards.”

Typically, at least one electrical connector couples each daughter board to the back plane. An electrical connector generally consists of two plastic housings. One plastic housing is mounted to the daughter board, while the other plastic housing is mounted to the back plane. A daughter board is connected to the back plane by mating the connector housing on the daughter board with the connector housing on the back plane.

Electrical connectors most commonly have many rows of signal contacts disposed within each plastic housing that generally have tails that extend from each connector housing, and attach to either the daughter board or the back plane. In applications that require fast data rates the signal contacts are very small and fragile.

When routing electronic signals between a daughter board and the back plane, each signal contact in one connector housing must touch its corresponding signal contact in the mated connector housing. In order to accomplish this, the two connector housings need to be properly aligned when connected. If proper alignment is not achieved during mating of the two connector housings, the very small and fragile signal contacts can become damaged or broken. As a result, some electronic signals may not be properly routed between the daughter board and the back plane, resulting in equipment failure.

One way to achieve proper alignment when plugging a daughter board onto the back plane is to provide guide pins on the back plane. Guide pins are typically mounted to the back plane so that they extend in a perpendicular orientation from the back plane. At least one guide pin is generally provided for each electrical connector mounted to the daughter board. When the daughter board is plugged onto the back plane, at least one guide pin engages a hole located on the connector housing mounted to the daughter board.

One prior art use of guide pins consists of mounting stainless steel pins to the back plane. One advantage of steel guide pins is that they are very strong, being able to withstand a substantial amount of side force without deflecting.

Other prior art guide pins have been made of plastic, but have been found to be lacking in the strength provided by stainless steel. The instant invention seeks to use a durable polyether imide plastic that can take the forces without deformation, while at the same time maintaining flexibility at the tip to allow for more successful connections without the use of stainless steel in producing the guide pins.

### SUMMARY OF THE INVENTION

The preferred embodiment of the present invention teaches a guiding module for a backplane comprising a base having a top side and a bottom side; a mounting member located on the bottom side of the base for attachment to a backplane; one or more guiding pins mounted on the top side of the base wherein the guiding pins are located in a substantially parallel orientation to each other and 180 degrees from the mounting member and wherein the guiding pins include shafts with flexible tips that are positioned on the guiding pins at the distal end from the base that allow for a slight displacement of the tips from the parallel orientation.

The above embodiment can be further modified to define that the one or more guiding pins are made of a high impact polyether imide plastic that allows the pins to remain firm at the shaft and that allows slight flexibility at the tips.

An alternative embodiment teaches a method of connecting a backplane with a daughter board comprising the steps of mounting a guide module to the backplane adjacent a plurality of connector pins to be connected to a daughter board, the guide module comprising a base having a top side and a bottom side; a mounting member located on the bottom side of the base for attachment to the backplane; one or more guiding pins mounted on the top side of the base wherein the guiding pins are located in a substantially parallel orientation to each other and 180 degrees from the mounting member and wherein the guiding pins include shafts with flexible tips that are positioned on the guiding pins at the distal end from the base that allow for a slight displacement of the tips from the parallel orientation; locating the daughter board that is attached to an electrical connector housing having one or more apertures, the apertures to mate with the one or more guiding pins wherein the connector housing contains connector receptacles to receive the plurality of connector pins; placing the one or more apertures proximate the flexible tips of the guiding pins; moving the one or more apertures to a position to completely mate with the guiding pins.

The above embodiment can be further modified by defining that the one or more guiding pins are made of a high impact polyether imide plastic that allows the pins to remain firm at the shaft and that allows slight flexibility at the tips.

### BRIEF DESCRIPTION OF THE DRAWINGS

This invention can better be understood by reference to the drawings, provided for exemplary purposes, and in which:

FIG. 1 is a perspective view of the guiding module of the instant invention.

FIG. 2 is a side view of the instant invention showing the deflection of one of the pins.

FIG. 3 is a close up view of one of the pins and its deflection.

FIG. 4 is a side view of the guiding module of the instant invention as it connects a daughter board to a back plane.

FIG. 5 is a side view of the guiding module as it mates completely a daughter board to a back plane.

### DETAILED DESCRIPTION OF A PREFERRED EMBODIMENTS

The instant invention describes a flexible guiding module for electronic connector backplane enclosures. The flexible guiding module has one or more molded plastic prongs or protrusions from a base body that is attached to the back plane by a threaded screw and secured to the base body by a threaded insert or directly by a threaded hole in the base body.

The plastic prongs or protrusions are molded of high impact polyether imide plastic having a spring back memory giving flexible guidance at the top or tip of the prongs or protrusions and gradually having additionally more accurate alignment at the base body when mated with the plug in card. Polyether imide plastic is considered an advanced thermoplastic which has both ether links and imide groups in its polymer chain. Polyether imide has gained rapid acceptance as a high temperature engineering thermoplastic material that exhibits high tensile strength without the use of reinforcement, flame resistance, very low smoke emission and excellent hydrolytic stability. In contrast to existing traditional fixed metal guiding pins that are currently available, this flexible plastic guiding module is also resilient to damage caused by bent metal pins that can damage the plug in card or daughter card.

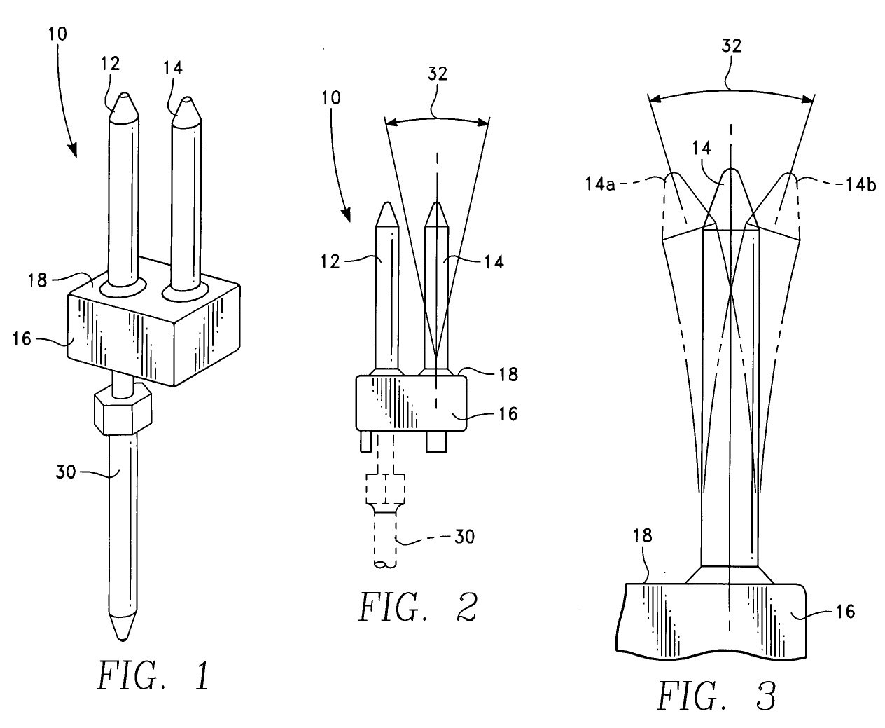

FIG. 1 shows the connector module 10 of the instant invention. The module 10 includes one or more pins 12, and in this illustration, two pins 12, 14 are shown. The pins 12, 14 are supported by a base 16. The base 16 has a top side 18 from which the pins 12, 14 extend in a perpendicular direction. The base 16 also has a bottom side from which an anchoring screw 30 extends in a perpendicular direction, 180 degrees from where the pins 12, 14 extend.

As seen in FIG. 2, the pins 12, 14 are made of a high impact plastic that keeps the pins 12, 14 strong, while at the same time allowing for flex in the tip, demonstrated by the arrow 32. FIG. 3 shows this in greater detail as the tip can extend in one direction 14a and the opposite direction 14b from the center, thereby allowing for ease of connection, while minimizing the possibility for breakage during connection.

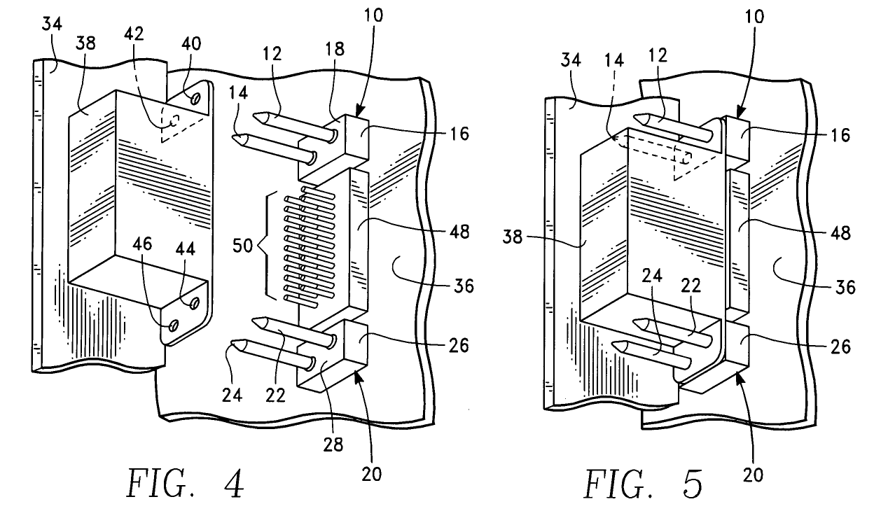

FIGS. 4 and 5 show the module 10 along with a second module 20 that has two prongs 22, 24, a base, 26 and a top of that base 28. FIG. 4 shows the position of all parts prior to connection and is FIG. 5 shows the position of all parts once connection has been made.

The daughter board 34 is shown positioned adjacent to the back plane 36. The rigid back plane 36 is shown vertically oriented. It serves as a mounting base for the guide pins 12, 14, 22, 24, which extend in a perpendicular direction from the back plane 36.

As illustrated, the electrical connector housing 38 has four alignment holes 40, 42, 44, 46. The housing 38 is mounted to the daughter board 34. The electrical contacts in the connector housing 38 are found in the connector receptacles, which are not shown. The electrical connector housing 48 is shown mounted to the back plane 36. The connector pins 50 serve as the electrical contacts disposed in the connector housing 48.

Once connected (FIG. 5), the daughter board 34 is positioned to the back plane 36. When the daughter board 34 is plugged onto the back plane 36, the guide pins 12, 14, 22, 24 engage alignment holes 40, 42, 44, 46, with flexibility and ease due to the make up of the guide pins 12, 14, 22, 24 thereby permitted proper alignment of the connector receptacles relative to the connector pins 50. Because of this, damage to the connector pins 50 is prevented.

The illustrations and examples provided herein are for explanatory purposes only and are not intended to limit the scope of the appended claims. This disclosure is to be considered an exemplification of the principles of the invention and is not intended to limit the spirit and scope of the invention and/or claims of the embodiment illustrated. Those skilled in the art will make modifications to the invention for particular applications of the invention.

The discussion included in this patent is intended to serve as a basic description. The reader should be aware that the specific discussion may not explicitly describe all embodiments possible and alternatives are implicit. Also, this discussion may not fully explain the generic nature of the invention and may not explicitly show how each feature or element can actually be representative or equivalent elements. Again, these are implicitly included in this disclosure. Where the invention is described in device-oriented terminology, each element of the device implicitly performs a function. It should also be understood that a variety of changes may be made without departing from the essence of the invention. Such changes are also implicitly included in the description. These changes still fall within the scope of this invention.

Further, each of the various elements of the invention and claims may also be achieved in a variety of manners. This disclosure should be understood to encompass each such variation, be it a variation of any apparatus embodiment, a method embodiment, or even merely a variation of any element of these. Particularly, it should be understood that as the disclosure relates to elements of the invention, the words for each element may be expressed by equivalent apparatus terms even if only the function or result is the same. Such equivalent, broader, or even more generic terms should be considered to be encompassed in the description of each element or action. Such terms can be substituted where desired to make explicit the implicitly broad coverage to which this invention is entitled. It should be understood that all actions may be expressed as a means for taking that action or as an element which causes that action. Similarly, each physical element disclosed should be understood to encompass a disclosure of the action which that physical element facilitates. Such changes and alternative terms are to be understood to be explicitly included in the description.

What is claimed is:

1. A guiding module for a backplane comprising
a base having a top side and a bottom side;
a mounting member located on said bottom side of said base for attachment to a backplane;
one or more guiding pins mounted on said top side of said base wherein said guiding pins are located in a substantially parallel orientation to each other and 180 degrees from said mounting member and wherein said guiding pins include shafts with flexible tips that are positioned on said guiding pins at the distal end from said base that allow for a slight displacement of said tips from said parallel orientation.

2. The guiding module of claim 1 wherein said one or more guiding pins are made of a high impact polyether imide plastic that allows said pins to remain firm at said shaft and that allows slight flexibility at said tips.

3. A method of connecting a backplane with a daughter board comprising the steps of
mounting a guide module to said backplane adjacent a plurality of connector pins to be connected to a daughter board, said guide module comprising
a base having a top side and a bottom side;
a mounting member located on said bottom side of said base for attachment to said backplane;
one or more guiding pins mounted on said top side of said base wherein said guiding pins are located in a substantially parallel orientation to each other and 180 degrees from said mounting member and wherein said guiding pins include shafts with flexible tips that are positioned on said guiding pins at the distal end from said base that allow for a slight displacement of said tips from said parallel orientation;
locating said daughter board that is attached to an electrical connector housing having one or more apertures, said apertures to mate with said one or more guiding pins wherein said connector housing contains connector receptacles to receive said plurality of connector pins;
placing said one or more apertures proximate said flexible tips of said guiding pins;
moving said one or more apertures to a position to completely mate with said guiding pins.

4. The method as defined in claim 3 wherein said one or more guiding pins are made of a high impact polyether imide plastic that allows said pins to remain firm at said shaft and that allows slight flexibility at said tips.
